(19) United States
(12) Patent Application Publication
(10) Pub. No.: US 2025/0194158 A1
(43) Pub. Date: Jun. 12, 2025

(54) THIN FILM TRANSISTOR AND MANUFACTURING METHOD THEREFOR

(71) Applicant: JUSUNG Engineering Co., Ltd., Gwangju-si, Gyeonggi-do (KR)

(72) Inventors: Il Houng PARK, Gwangju-Si, Gyeonggi-Do (KR); Seung Hyun CHO, Gwangju-Si, Gyeonggi-Do (KR); Yun Gu YEO, Gwangju-Si, Gyeonggi-Do (KR); Won Ju OH, Gwangju-Si, Gyeonggi-Do (KR); Dong Hwan LEE, Gwangju-Si, Gyeonggi-Do (KR); Jun Seok LEE, Gwangju-Si, Gyeonggi-Do (KR); Jeong HEO, Gwangju-Si, Gyeonggi-Do (KR); Chul Joo HWANG, Gwangju-Si, Gyeonggi-Do (KR)

(21) Appl. No.: 18/845,921

(22) PCT Filed: Mar. 10, 2023
(86) PCT No.: PCT/KR2023/003298

§ 371 Date: Sep. 11, 2024

(30) Foreign Application Priority Data
Mar. 14, 2022 (KR) 10-2022-0031539
Apr. 4, 2022 (KR) 10-2022-0041847
Apr. 7, 2022 (KR) 10-2022-0043467

(51) Int. Cl. H10D 30/67; H01L 21/443; H10D 30/01; H10D 62/80; H10D 64/01; H10D 64/62

(52) U.S. Cl. CPC H10D 30/6737; H01L 21/443; H10D 30/031; H10D 64/01; H10D 64/62; H10D 30/6755; H10D 62/875

(57) ABSTRACT

Provided are a thin film transistor and a method for manufacturing the same, and more particularly, to a thin film transistor having improved characteristics and a method for manufacturing the same. A thin film transistor in accordance with an exemplary embodiment includes a gate electrode, an active layer containing oxide of a first metal element and disposed to be vertically spaced apart from the gate electrode, source and drain electrodes disposed to be spaced apart from each other on the active layer, and a contact layer disposed between the active layer and the source and drain electrodes.

### TECHNICAL FIELD

The present disclosure relates to a thin film transistor and a method for manufacturing the same, and more particularly, to a thin film transistor having improved characteristics and a method for manufacturing the same.

### BACKGROUND ART

A thin film transistor (TFT) is used as a circuit for independently driving each pixel in a semiconductor element, a liquid crystal display (LCD), an organic electroluminescence (EL) display, and the like.

The thin film transistor is formed together with a gate line and a data line on a lower substrate of the display device. That is, the thin film transistor is constituted by a gate electrode that is a portion of the gate line, an active layer used as a channel, a source electrode and a drain electrode, which are portions of the data line, and a gate insulating layer.

In a process of manufacturing the film transistor, an active layer is exposed to an etching gas for patterning. When the active layer is exposed to the etching gas, an exposed surface of the active layer is damaged by the etching gas to lose oxygen. In addition, the active layer is connected to the source electrode and the drain electrode, which are the portions of the data line. Here, when the thin film transistor is driven, oxygen moves from the active layer to the source electrode and the drain electrode, and thus, the active layer loses oxygen. As described above, when oxygen deficiency occurs in the active layer, the active layer unintentionally increases in electrical conductivity to function as a conductor. Thus, there is a limitation in that the thin film transistor is not stably driven due to an element short circuit.

### RELATED ART DOCUMENT

### Patent Document

(Patent Document 1) KR10-2004-0013273 A

### SUMMARY

### Technical Problem

The present disclosure provides a thin film transistor capable of preventing oxygen deficiency in an active layer from occurring and improving stability at the same time, and a method for manufacturing the same.

### Technical Solution

In accordance with an exemplary embodiment, a thin film transistor includes: a gate electrode; an active layer containing oxide of a first metal element and disposed to be vertically spaced apart from the gate electrode; source and drain electrodes disposed to be spaced apart from each other on the active layer; and a contact layer containing a second metal element and disposed between the active layer and the source and drain electrodes.

The contact layer may contain a metal or alloy containing the second metal element.

The second metal element may include ruthenium.

The contact layer may contain oxide of the second metal element.

The oxide of the first metal element and the oxide of the second metal element may have compositions different from each other.

Each of the oxide of the first metal element and the oxide of the second metal element may contain zinc oxide doped with impurities, and the oxide of the first metal element and the oxide of the second metal element may have contents of the impurities, which are different from each other.

The oxide of the second metal element may have a content of the impurities, which is greater than that of the oxide of the first metal element.

The impurities may include at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (TI), silicon (Si), germanium (Ge), tin (Sn), lead (Pb), phosphorus (P), or arsenic (As).

The oxide of the first metal element may contain impurities of approximately 20 at % or more and less than approximately 40 at % with respect to the entire oxide of the first metal element, and the oxide of the second metal element may contain impurities of approximately 40 at % or more and less than approximately 60 at % with respect to the entire oxide of the second metal element.

The oxide of the second metal element may have a content of oxygen (O) less than that of the oxide of the first metal element.

The contact layer may have a thickness of approximately 30 Å to approximately 100 Å.

The thin film transistor may further include an insulating layer disposed on the active layer and having a contact hole through which a portion of a surface of the active layer is exposed, wherein the contact layer may be disposed on the portion of the surface of the active layer, which is exposed by the contact hole, and the source and drain electrodes may be in contact with the contact layer to extend onto the insulating layer.

In accordance with another exemplary embodiment, a method for manufacturing a thin film transistor includes: preparing a substrate on which a gate electrode and an active layer disposed to be vertically spaced apart from the gate electrode are formed; and forming a contact layer for connecting the active layer to source and drain electrodes on the active layer.

The preparing of the substrate may include preparing a substrate on which an insulating layer having a contact hole, through which a portion of a surface of the active layer is exposed, on the active layer, and the forming of the contact layer may include forming the contact layer on the portion of the surface of the active layer, which is exposed by the contact hole.

In the forming of the contact layer, the contact layer may be formed to a thickness of approximately 30 Å to approximately 100 Å on the portion of the surface of the active layer.

The forming of the contact layer may be performed by an atomic layer deposition process in which a process cycle including supplying a source gas containing a metal element onto the active layer and supplying a reactant gas containing oxygen onto the active layer is repeated several times.

In the supplying of the source gas, a first source gas containing zinc (Zn) and a second source gas containing at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (TI), silicon (Si), germanium (Ge), tin (Sn), lead (Pb), phosphorus (P), or arsenic (As) may be supplied at the same time.

In the supplying of the source gas, the source gas may be controlled to be supplied so that a supply amount of second source gas is greater than a supply amount of first source gas.

The method may further include forming source and drain electrodes on the contact layer.

In accordance with yet another exemplary embodiment, a thin film transistor includes: a gate electrode; an active layer containing oxide of a first metal element and disposed to be vertically spaced apart from the gate electrode; a first insulating layer disposed on the active layer and having a first contact hole through which a portion of a surface of the active layer is exposed; a second insulating layer disposed on the first insulating layer and exposing the first contact hole and a portion of a surface of the first insulating layer extending from the first contact hole; a contact layer containing a second metal element and disposed on the portion of the surface of the active layer, which is exposed by the first insulating layer; and source and drain electrodes disposed to be spaced apart from each other on the contact layer and extending onto the portion of the surface of the first insulating layer, which is exposed by the second insulating layer.

The first insulating layer may contain silicon oxide, and the second insulating layer may contain silicon nitride.

The first metal element may contain at least one of indium (In), gallium (Ga), or zinc (Zn), and the second metal element contains at least one of indium (In), gallium (Ga), zinc (Zn), or ruthenium (Ru).

In accordance with still another exemplary embodiment, a method for manufacturing a thin film transistor includes: preparing a substrate on which a gate electrode and an active layer which is disposed to be vertically spaced apart from the gate electrode and of which a portion of a surface is exposed by a contact hole formed in a first insulating layer; and forming a second insulating layer containing silicon nitride on the first insulating layer.

In accordance with even another exemplary embodiment, a method for manufacturing a thin film transistor includes: preparing a substrate on which a gate electrode and an active layer which is disposed to be vertically spaced apart from the gate electrode and of which a portion of a surface is exposed by a contact hole formed in each of a first insulating layer and a second insulating layer, which are laminated; and forming a contact layer for connecting the active layer to source and drain electrodes on the portion of the exposed surface of the active layer in an area selective-atomic layer deposition method.

The contact layer may contain metal oxide doped with impurities.

The impurities may include at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (TI), silicon (Si), germanium (Ge), tin (Sn), lead (Pb), phosphorus (P), or arsenic (As).

The method may further include, after the forming of the contact layer, etching the metal oxide layer doped with the impurities, which is formed on the second insulating layer.

The metal oxide layer doped with the impurities may be etched with hydrogen bromide (HBr).

In accordance with yet still another exemplary embodiment, a method for manufacturing a thin film transistor includes: preparing a substrate on which a gate electrode and an active layer which is disposed to be vertically spaced apart from the gate electrode and of which a portion of a surface is exposed by a first contact hole formed in a first insulating layer containing silicon oxide; forming a second insulating layer, in which a second contact hole exposing the first contact hole is formed and which contains silicon nitride, on the first insulating layer; and forming a contact layer for connecting the active layer to source and drain electrodes on the portion of the exposed surface of the active layer in an area selective-atomic layer deposition method.

In accordance with even still another exemplary embodiment, a thin film transistor includes: a gate electrode; an active layer disposed to be vertically spaced apart from the gate electrode and containing at least one of indium (In), gallium (Ga), or zinc (Zn); source and drain electrodes disposed to be spaced apart from each other on the active layer; and a ruthenium oxide layer disposed between the active layer and the source and drain electrodes.

In accordance with even yet still another exemplary embodiment, a thin film transistor includes: a gate electrode; an active layer disposed to be vertically spaced apart from the gate electrode and containing at least one of indium (In), gallium (Ga), or zinc (Zn); source and drain electrodes disposed to be spaced apart from each other on the active layer; a highly concentrated metal oxide layer disposed between the active layer and the source and drain electrodes and having a content of impurities, which is greater than that of the active layer; and a ruthenium oxide layer disposed between the highly concentrated metal oxide layer and the source and drain electrodes.

In accordance with even yet still further another exemplary embodiment, a method for manufacturing a thin film transistor includes: preparing a substrate on which a gate electrode and an active layer disposed to be vertically spaced apart from the gate electrode are formed; and forming a ruthenium oxide layer for connecting the active layer to source and drain electrodes on the active layer.

In accordance with even yet still further another exemplary embodiment, a method for manufacturing a thin film transistor includes: preparing a substrate on which a gate electrode and an active layer disposed to be vertically spaced apart from the gate electrode are formed; forming a highly concentrated metal oxide layer having a content of impurities, which is greater than that of the active layer, on the active layer; and forming a ruthenium oxide layer for connecting the active layer to source and drain electrodes on the highly concentrated metal oxide layer.

The impurities may include at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (TI), silicon (Si), germanium (Ge), tin (Sn), lead (Pb), phosphorus (P), or arsenic (As).

### Advantageous Effects

According to the exemplary embodiments, the contact layer for preventing the oxygen deficiency in the active layer may be provided between the active layer and the source and drain electrodes to prevent the active layer from being conductive and improve the switching characteristics.

In addition, the contact resistance between the active layer and the source and drain electrodes may be effectively reduced, and the characteristics and reliability of the element may be improved.

### BRIEF DESCRIPTION OF THE DRAWINGS

FIG. 1 is a schematic view illustrating a thin film transistor in accordance with an exemplary embodiment;

FIG. 2 is a schematic view illustrating a thin film transistor in accordance with another exemplary embodiment;

FIGS. 3A, 3B and 3C are schematic views illustrating a method for manufacturing a thin film transistor in accordance with an exemplary embodiment;

FIGS. 4A, 4B and 4C are schematic views illustrating a method for manufacturing a thin film transistor in accordance with another exemplary embodiment;

FIG. 5 is a schematic view illustrating a thin film transistor in accordance with further another exemplary embodiment; and

FIG. 6 is a schematic view illustrating a thin film transistor in accordance with still another exemplary embodiment.

### DETAILED DESCRIPTION OF EXEMPLARY EMBODIMENTS

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a region, or a substrate is referred to as being ‘on’ another one, it can be directly on the other one, or one or more intervening layers, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and regions may be exaggerated for clarity of illustration. Like reference numerals refer to like elements throughout.

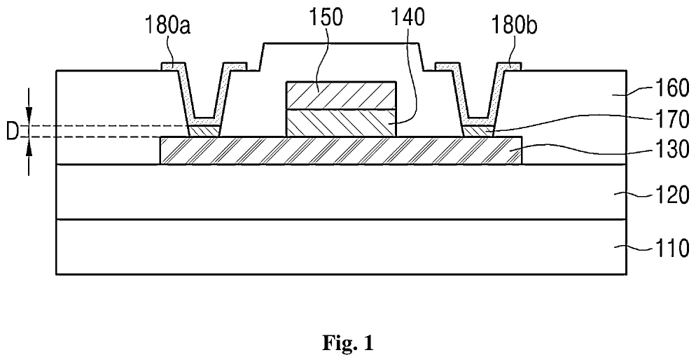

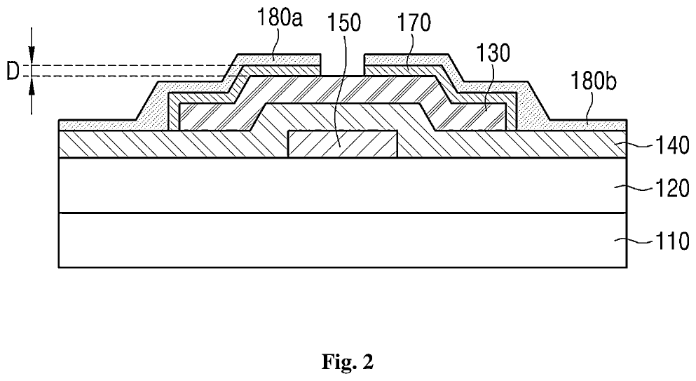

FIG. 1 is a schematic view illustrating a thin film transistor in accordance with an exemplary embodiment, and FIG. 2 is a schematic view illustrating a thin film transistor in accordance with another exemplary embodiment.

Referring to FIGS. 1 and 2, a thin film transistor in accordance with an exemplary embodiment includes a gate electrode 150, an active layer 130 disposed to be vertically spaced apart from the gate electrode 150, source and drain electrodes 180a and 180b disposed to be spaced apart from each other on the active layer 130, and a contact layer 170 disposed between the active layer 130 and the source and drain electrodes 180a and 180b.

As illustrated in FIG. 1, the thin film transistor in accordance with an exemplary embodiment may be a top gate-type thin film transistor including an active layer 130 disposed on a substrate 110, a gate insulating layer 140 disposed on the active layer 130, a gate electrode 150 disposed on the gate insulating layer 140, a source electrode 180a and a drain electrode 180b, which are disposed to be spaced apart from each other on the active layer 130 with the gate insulating layer 140 and the gate electrode 150 therebetween, and contact layers 170 respectively disposed between the active layer 130 and the source electrode 180a and between the active layer 130 and the drain electrode 180b.

A transparent substrate may be used as the substrate 110. For example, a silicon substrate, a glass substrate, or a plastic substrate when implementing a flexible display may be used as the substrate 110. In addition, a reflective substrate may be used as the substrate 110, and in this case, a metal substrate may be used. The metal substrate may be made of stainless steel (SUS), titanium (Ti), molybdenum (Mo), or an alloy thereof. A buffer layer 120 may be disposed on the substrate 110. Here, the buffer layer 120 may be made of an insulating material including silicon oxide (SiO₂).

The active layer 130 may be disposed on the buffer layer 120. The active layer 130 may be disposed on a predetermined area of the buffer layer 120, and the gate electrode 150 to be described below may be disposed to be spaced apart from an upper side of the active layer 130 to overlap a partial area of the active layer 130.

Here, the active layer 130 may be made of metal oxide. That is, the active layer 130 may be provided as a metal oxide thin film or a plurality of metal oxide thin films having different compositions. For example, the active layer 130 may include oxide including at least one of indium (In), gallium (Ga), and zinc (Zn).

In the related art, the active layer has been made using amorphous silicon or crystalline silicon. However, since the substrate of the thin film transistor using silicon has to use a glass substrate, the substrate is not only heavy, but also has a disadvantage in that it is not used as a flexible display device. As a result, to implement a high-speed device, that is, to improve mobility, a metal oxide thin film having high carrier concentration and excellent electrical conductivity may be used as the active layer.

In addition, the active layer 130 may be made of a material including zinc oxide doped with impurities. Here, the impurities may include at least one material of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), thallium (TI), silicon (Si), germanium (Ge), tin (Sn), lead (Pb), phosphorus (P), arsenic (As), antimony (Sb), or bismuth (Bi).

For example, indium (In) may be a metal having a relatively low band gap and a relatively high standard electrode potential and thus may have characteristics of increasing in charge concentration and improving mobility. On the other hand, gallium (Ga) may be a metal having a relatively high band gap and a relatively low standard electrode potential and thus may have characteristics of reducing a charge concentration and improving stability. Thus, the electrical conductivity of the active layer 130 may be adjusted by controlling a content of the impurities contained in the metal oxide thin film. As described above, the active layer 130 made of the metal oxide has a characteristic in which the electrical conductivity decreases as the oxygen content increases, and the electrical conductivity increases as the oxygen content decreases.

In addition, the active layer 130 may include magnesium (Mg) as an impurity to form a p-type active layer and include silicon (Si) as an impurity to form an n-type active layer. In addition, the active layer 130 may include various noble metals such as ruthenium (Ru), platinum (Pt), gold (Au), silver (Ag), rhodium (Rh), palladium (Pd), osmium (Os), iridium (Ir), yttrium (Yi), tungsten (W), molybdenum (Mo), and the like.

A gate insulating layer 140 may be disposed on the active layer 130. As described above, the gate insulating layer 140 may be disposed on a partial area of the active layer 130, and the gate insulating layer 140 may be made of one or more insulating materials of inorganic insulating layers including silicon oxide (SiO₂), silicon nitride (SiN), alumina (Al₂O₃), and zirconia (ZrO₂) having excellent adhesion to metal materials and excellent dielectric strength.

The gate electrode 150 may be formed on the gate insulating layer 140. The gate electrode 150 may be made of a conductive material, for example, at least one metal of aluminum (Al), neodymium (Nd), silver (Ag), chromium (Cr), titanium (Ti), tantalum (Ta), molybdenum, or an alloy thereof. In addition, the gate electrode 150 may be formed not only as a single layer but also as a multi-layer including a plurality of metal layers. That is, the gate electrode 150 may be formed as a double layer including a metal layer made of chromium (Cr), titanium (Ti), tantalum (Ta), and molybdenum (Mo), which have excellent physical and chemical properties, and a metal layer made of aluminum (Al) series, silver (Ag) series or copper (Cu) series, which have low specific resistance.

An insulating layer 160 having a contact hole which covers the gate electrode 150 and through which a portion of a surface of the active layer 130 is exposed at both sides of the gate electrode 150 may be disposed on the active layer 130. That is, a contact hole may be defined in the insulating layer 160 so that each of the source electrode 180a and the drain electrode 180b is electrically connected to the active layer 130 through the contact hole. The insulating layer 160 may be made of an insulating material including silicon oxide (SiO₂).

A contact layer 170 is disposed on a portion of the surface of the active layer 130, which is exposed by the contact hole. The contact layer 170 includes a metal element. That is, the contact layer 170 may be made of a metal or an alloy. Here, the contact layer 170 may be made of ruthenium (Ru) or a ruthenium (Ru) alloy. Also, the contact layer 170 may be made of metal oxide. That is, the contact layer 170 may include a metal oxide thin film. Here, the contact layer 170 may be provided as a single metal oxide thin film or a plurality of metal oxide thin films having different compositions, like the active layer 130. For example, the contact layer 170 may include ruthenium oxide. In addition, the contact layer 170 may be made of a material including zinc oxide doped with impurities. Here, the impurities may include at least one material of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), thallium (TI), silicon (Si), germanium (Ge), tin (Sn), lead (Pb), phosphorus (P), arsenic (As), antimony (Sb), or bismuth (Bi).

The contact layer 170 may be made of metal oxide having a composition different from that of the metal oxide forming the active layer 130. That is, when the metal oxide contained in the active layer 130 is referred to as oxide of a first metal element, and the metal oxide contained in the contact layer 170 is referred to as oxide of a second metal element, the oxide of the first metal element may have a composition different from that of the oxide of the second metal element. Here, when the oxide of each of the first metal element and the second metal element includes zinc oxide doped with an impurity, the oxide of the second metal element may have a larger content of impurities, which includes at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), thallium (TI), silicon (Si), germanium (Ge), tin (Sn), lead (Pb), phosphorus (P), arsenic (As), antimony (Sb), or bismuth (Bi), than the oxide of the first metal element. For example, when the oxide of the first metal element that forms the active layer 130 contains impurities of approximately 20 at % or more and less than approximately 40 at % with respect to the entire oxide of the first metal element, the oxide of the second metal element may contain impurities of approximately 40 at % or more and less than approximately 60 at % with respect to the entire oxide of the second metal element. As described above, the oxide of the second metal element having a high content of the impurities may have a content of oxygen (O) less than that of the oxide of the first metal element.

If the contact layer 170 is not provided, and the source electrode 180a and the drain electrode 180b are disposed on the active layer 140, the active layer 130 may be exposed to an etching gas in the process of forming the contact hole in the insulating layer 160 to form the source electrode 180a and the drain electrode 180b. When the active layer 130 is exposed to the etching gas, the active layer 130 may be damaged by the etching gas from the surface thereof to a predetermined depth to lose oxygen and then become an oxygen deficient state. In addition, when the source electrode 180a and the drain electrode 180b are directly disposed on the surface of the active layer 130 damaged by the etching gas as described above, oxygen may move from the active layer 130 to the source electrode 180a and the drain electrode 180b when the thin film transistor is driven. As described above, when the oxygen deficiency occurs in the active layer, the active layer may unintentionally increase in electrical conductivity and thus become conductive, and an element short circuit may occur so that the thin film transistor is not stably driven.

On the other hand, when the contact layer 170 made of a metal, an alloy, or metal oxide is disposed between the active layer 130 and the source and drain electrodes 180a and 180b as in the exemplary embodiment, the oxygen or a metal material contained in the contact layer 170 may be filled into a site at which oxygen is escaped from the active layer 130. That is, the metal element or oxygen contained in the contact layer 170 may be diffused at the site at which oxygen is escaped from the active layer 130 to prevent oxygen from moving from the active layer 130 to the source electrode 180a and the drain electrode 180b and also prevent the active layer from becoming conductive.

In this case, the contact layer 170 may have a thickness D of approximately 30 Å to approximately 100 Å. Here, when the contact layer 170 has a thickness of less than approximately 30 Å, a sufficient oxygen migration prevention effect may not be obtained, and when the contact layer 170 has a thickness exceeding approximately 100 Å, a process time may excessively increase to cause a limitation in which miniaturization of the thin film transistor is inhibited. Therefore, the contact layer 170 may preferably have a thickness of approximately 30 Å to approximately 100 Å.

The source electrode 180a and the drain electrode 180b are disposed on the contact layer 170. That is, each of the source electrode 180a and the drain electrode 180b may be provided to be in contact with the contact layer 170 disposed in the contact hole so that the source electrode 180a and the drain electrode 180b are spaced apart from each other with the gate electrode 150 therebetween. Here, the source electrode 180a and the drain electrode 180b may be provided to be contact with the contact layer 170 so as to extend onto the insulating layer 160. The source electrode 180a and the drain electrode 180b may be formed by the same process using the same material and may be made of a conductive material, for example, may be made of at least one metal of aluminum (Al), neodymium (Nd), silver (Ag), chromium (Cr), titanium (Ti), tantalum (Ta), and molybdenum (Mo), or an alloy thereof. That is, the gate electrode 150 may be made of the same material, but may be made of a different material. In addition, each of the source electrode 180a and the drain electrode 180b may be provided as a single layer or multiple layers. Here, the layers may include different metals or alloys, respectively.

As illustrated in FIG. 2, the thin film transistor in accordance with another exemplary embodiment may be a bottom gate-type thin film transistor including a gate electrode 150 disposed on a substrate 110, a gate insulating layer 140 disposed on the gate electrode 150, an active layer 130 disposed on the gate insulating layer 140, a source electrode 180a and a drain electrode 180b, which are disposed to be spaced apart from each other on the active layer 130, and contact layers 170 respectively disposed between the active layer 130 and the source electrode 180a and between the active layer 130 and the drain electrode 180b.

Even in the case of such the bottom gate-type thin film transistor, the contents in relation to the thin film transistor of FIG. 1 may be applied as they are. That is, even in the case of the thin film transistor in accordance with another exemplary embodiment, the contact layers 170 may be disposed between the active layer 130 and the source electrode 180a and between the active layer 130 and the drain electrode 180b, respectively. As described above, even in the case of the thin film transistor in accordance with another exemplary embodiment, the contents described in the thin film transistor in accordance with the foregoing exemplary embodiment may be applied as they are except for a stacking order of the gate insulating layer 140 and the gate electrode, and thus, duplicated descriptions will be omitted.

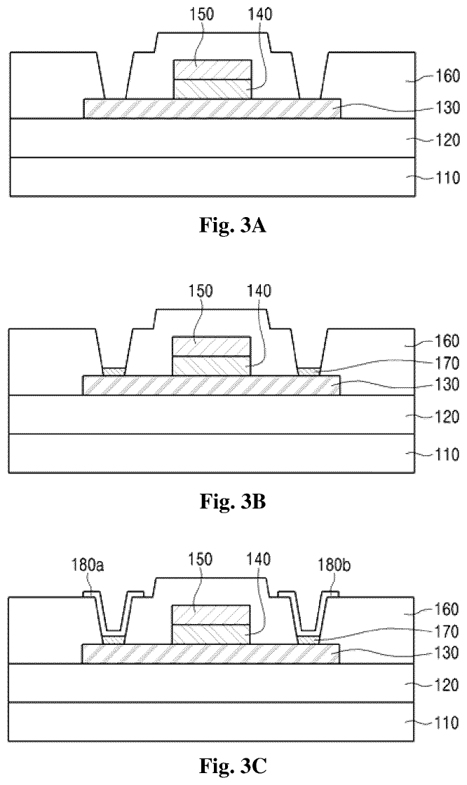

FIG. 3 is a schematic view illustrating a method for manufacturing a thin film transistor in accordance with an exemplary embodiment.

Referring to FIG. 3, a method for manufacturing a thin film transistor in accordance with an exemplary embodiment includes a process of preparing a substrate 110 on which a gate electrode 150 and an active layer 130 disposed to be vertically spaced apart from the gate electrode 150 are formed, and a process of forming a contact layer 170 for connecting the active layer 130 to each of a source electrode 180a and a drain electrode 180b.

First, in the process of preparing the substrate 110, as illustrated in FIG. 3A, the substrate 110 on which the gate electrode 150 and the active layer 130 disposed to be vertically spaced apart from the gate electrode 150 are formed is prepared. Here, in the process of preparing the substrate 110, to manufacture a top gate-type thin film transistor, the substrate 110, in which the active layer 130 is formed on the substrate 110, the gate insulating layer 140 is formed on the active layer 130, and the gate electrode 150 is formed on the gate insulating layer 140 may be prepared. In addition, a buffer layer 120 may be further formed between the substrate 110 and the active layer 130, and an insulating layer 160 having a contact hole through which a portion of a surface of the active layer 130 is exposed to form the source electrode 180a and the drain electrode 180b may be further formed on the active layer 130.

In the process of forming the contact layer 170, as illustrated in FIG. 3B, the contact layer 170 for connecting the active layer 130 to each of the source electrode 180a and the drain electrode 180b is formed on the active layer 130. Here, the contact layer 170 may be formed on a portion of the surface of the active layer 130, which is exposed by the contact hole of the insulating layer 160.

As described above, the contact layer 170 may be formed of a metal, an alloy, or metal oxide. The contact layer 170 may be formed through various thin film formation processes. For example, to form the contact layer 170 using metal oxide, the process of forming the contact layer 170 may be performed by repeatedly performing a process cycle including a process of supplying a source gas containing a metal element to the active layer 130 and a process of supplying a reactant gas containing oxygen to the active layer 130 several times. Such an atomic layer deposition process may be performed by repeatedly performing a process cycle, in which a process of supplying a source gas containing a metal element, a process of purging the source gas, a process of supplying a reactant gas containing oxygen, and a process of purging the reactant gas are sequentially performed, several times.

Here, in the process of supplying the source gas, a first source gas containing zinc (Zn) and a second source gas containing at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), thallium (TI), silicon (Si), germanium (Ge), tin (Sn), lead (Pb), phosphorus (P), arsenic (As), antimony (Sb), or bismuth (Bi) may be supplied at the same time. As described above, the first source gas containing zinc (Zn) and the second source gas containing impurities such as indium (In), gallium (Ga), and tungsten (W) may be supplied at the same time, and thus, the contact layer 170 may be formed using a material containing zinc oxide doped with the impurities such as indium (In), gallium (Ga), and tungsten (W).

In the process of supplying the source gas, the source gas may be controlled to be supplied so that a supply amount of second source gas is greater than a supply amount of first source gas. Thus, the metal oxide forming the contact layer 170 may be formed to contain impurities of approximately 40 at % or more and less than approximately 60 at % with respect to the total amount.

After the process of forming the contact layer 170, as illustrated in FIG. 3C, a process of forming the source electrode 180a and the drain electrode 180b on the contact layer 170 may be performed.

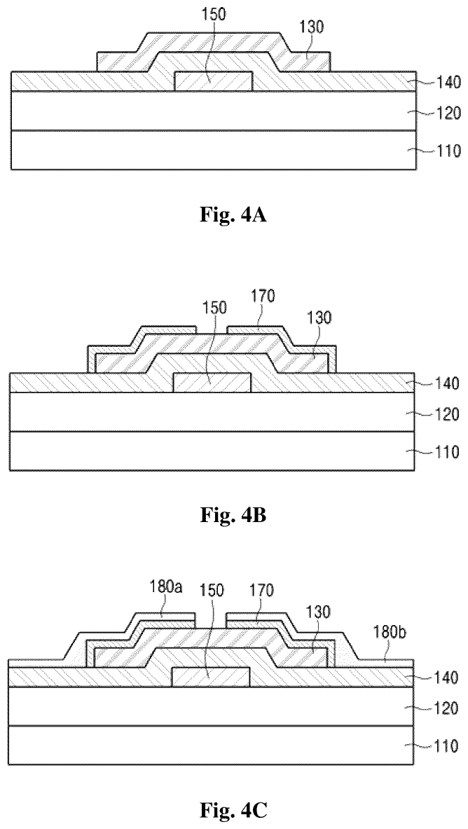

FIG. 4 is a schematic view illustrating a method for manufacturing a thin film transistor in accordance with another exemplary embodiment.

In a method for manufacturing a thin film transistor in accordance with another exemplary embodiment, in a process of preparing a substrate 110, to manufacture a bottom gate-type thin film transistor, a gate electrode 150 may be formed on a substrate 110, a gate insulating layer 140 may be formed on the gate electrode 150, and an active layer 130 may be formed on the gate insulating layer 140 to prepare the substrate 110. In addition, a buffer layer 120 may be further formed between the substrate 110 and the gate electrode 150.

In addition, although the contact layers 170 is illustrated as being formed to be separated from each other on different areas in FIG. 4, in the method for manufacturing the thin film transistor in accordance with further another exemplary embodiment, the contact layer 170 may be formed as a single layer that covers top and side surfaces of the active layer 130. Except for this structure, since the contents described in the method for manufacturing the thin film transistor according to the foregoing exemplary embodiment may be applied as they are, duplicated descriptions will be omitted.

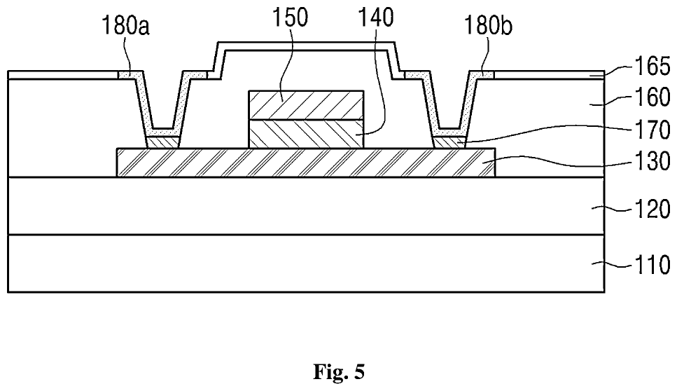

FIG. 5 is a schematic view illustrating a thin film transistor in accordance with further another exemplary embodiment.

Referring to FIG. 5, a thin film transistor in accordance with further another exemplary embodiment includes a gate electrode 150, an active layer 130 disposed to be vertically spaced apart from the gate electrode 150, a first insulating layer 160 disposed on the active layer 130 and having a first contact hole (not shown) through which a portion of a surface of the active layer 130 is exposed, a second insulating layer 165 disposed on the first insulating layer 160 and exposing the first contact hole and a portion of a surface of the first insulating layer 160 extending from the first contact hole, a contact layer 170 disposed on the portion of the surface of the active layer 130, which is exposed by the first insulating layer 160, and source and drain electrodes 180a and 180b disposed to be spaced apart from each other on the contact layer 170 and extending onto the portion of the surface of the first insulating layer 160, which is exposed by the second insulating layer 165.

The thin film transistor in accordance with further another exemplary embodiment may be different from the thin film transistor in accordance with an exemplary embodiment in that the second insulating layer 165 is additionally provided, and thus, the contents described in relation to the thin film transistor in accordance with an exemplary embodiment may be applied as they are. Here, since the first insulating layer 160 and the first contact hole of the thin film transistor in accordance with further another exemplary embodiment have the same configuration as the insulating layer 160 and the contact hole of the thin film transistor in accordance with the forgoing exemplary embodiment, it will be denoted with the same reference numeral.

In more detail, the thin film transistor in accordance with further another exemplary embodiment includes a gate electrode 150, an active layer 130 including oxide of a first metal element and disposed to be vertically spaced apart from the gate electrode 150, a first insulating layer 160 disposed on the active layer 130 and having a first contact hole through which a portion of a surface of the active layer 130 is exposed, a second insulating layer 165 disposed on the first insulating layer 160 and exposing the first contact hole and a portion of a surface of the first insulating layer 160 extending from the first contact hole, a contact layer 170 including a second metal element and disposed on the portion of the surface of the active layer 130, which is exposed by the first insulating layer 160, and source and drain electrodes 180a and 180b disposed to be spaced apart from each other on the contact layer 170 and extending onto the portion of the surface of the first insulating layer 160, which is exposed by the second insulating layer 165.

Here, the first insulating layer 160 and the second insulating layer 165 may have different compositions. That is, the first insulating layer 160 may include silicon oxide (SiO), and the second insulating layer 165 may include silicon nitride (SiN). Here, the second insulating layer 165 may be formed on the first insulating layer 160 and have a second contact hole greater than the first contact hole at a position overlapping the first contact hole defined in the first insulating layer 160. Thus, when the second insulating layer 165 is disposed on the first insulating layer 160, the first contact hole and the surface of the first insulating layer extending from the first contact hole may be exposed. In addition, the active layer 130 may be made of oxide of a first metal element including at least one of indium (In), gallium (Ga), or zinc (Zn), and the contact layer 170 may include the second metal element including at least one of indium (In), gallium (Ga), zinc (Zn), or ruthenium (Ru) as described above.

As described above, when the second insulating layer 165 is additionally disposed on the first insulating layer 160, the contact layer 170 may be formed in an area selective-atomic layer deposition (AS-ALD) method. Here, the area selective-atomic layer deposition method may refer to a method for depositing a thin film selectively only on a surface of a specific area by the atomic layer deposition method, and various known area selective-atomic layer deposition methods may be applied to form the contact layer 170. In addition, the contact layer 170 may be selectively formed on the portion of the exposed surface of the active layer 130 by using a deposition method using a mask.

That is, the method for manufacturing the thin film transistor in accordance with further another exemplary embodiment may include a process of preparing a substrate 110 on which a gate electrode 150 and an active layer 130, which is disposed to be vertically spaced apart from the gate electrode 150 and of which a portion of a surface is exposed by a first contact hole formed in a first insulating layer 160, and a process of forming a second insulating layer 165 containing silicon nitride on the first insulating layer 160. In this case, a portion of the surface of the active layer 130 may be exposed by the first contact hole and a second contact hole, which are respectively formed in the stacked first insulating layer 160 and the second insulating layer 165, and the contact layer 170 for connecting the active layer 130 to source and drain electrodes 180a and 180b in the area selective-atomic layer deposition method may be formed on the portion of the exposed surface of the active layer 130.

As described above, even when the contact layer 170 is selectively formed on the portion of the exposed surface of the active layer 130, a residual layer formed during the process of forming the contact layer 170 may be formed on the second insulating layer 165. For example, when the contact layer 170 contains metal oxide doped with impurities, the metal oxide layer doped with the impurities may remain on the second insulating layer 165. Therefore, in an exemplary embodiment, after the process of forming the contact layer 170, a process of etching the metal oxide layer doped with the impurities formed on the second insulating layer 165 may be further performed. Here, the metal oxide layer doped with the impurities may be etched with hydrogen bromide (HBr).

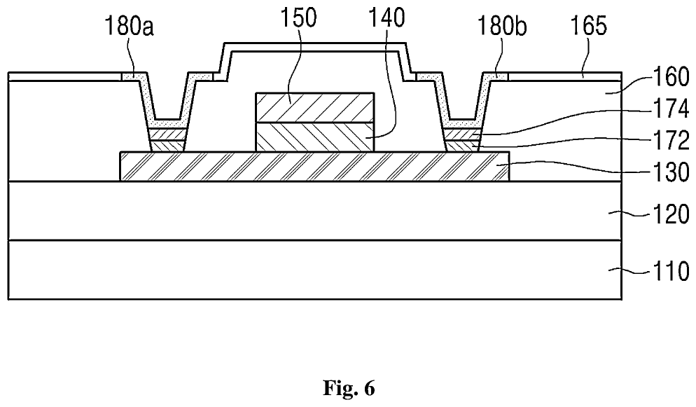

FIG. 6 is a schematic view illustrating a thin film transistor in accordance with still another exemplary embodiment.

Referring to FIG. 6, a thin film transistor in accordance with a still another exemplary embodiment includes a gate electrode 150, an active layer 130 disposed to be vertically spaced apart from the gate electrode 150, source and drain electrodes 180a and 180b disposed to be spaced apart from each other on the active layer 130, a ruthenium oxide layer 172 disposed between the active layer 130 and the source and drain electrodes 180a and 180b, and a highly concentrated metal oxide layer 174.

The thin film transistor in accordance with still further another exemplary embodiment may be different from the thin film transistor in accordance with further another exemplary embodiment in that the contact layer 170 is provided as the ruthenium oxide layer 172 and the highly concentrated metal oxide layer 174 disposed on the ruthenium oxide layer 172, and thus, the contents described in relation to the thin film transistor in accordance with further another exemplary embodiment may be applied as they are.

That is, the thin film transistor in accordance with still further exemplary embodiment may include a gate electrode 150, an active layer vertically spaced apart from the gate electrode 150 and containing at least one of indium (In), gallium (Ga), or zinc (Zn), source and drain electrodes 180a and 180b disposed to be spaced apart from each other on the active layer 130, a highly concentrated metal oxide layer 174 disposed between the active layer 130 and the source and drain electrodes 180a and 180b and having a content of impurities higher than that of the active layer 130, and a ruthenium oxide layer 172 disposed between the highly concentrated metal oxide layer 174 and the source and drain electrodes 180a and 180b.

As described above, the contact layer 170 may contain a metal element and may be provided as a plurality of metal oxide thin films having different compositions. Here, in the still fourth exemplary embodiment, the contact layer 170 may be provided in a plurality of thin films of a ruthenium oxide layer 172 containing oxide of ruthenium (Ru) and a highly concentrated metal oxide layer 174 containing metal oxide having a high impurity concentration. Here, the metal oxide may be oxide of at least one of indium (In), gallium (Ga), or zinc (Zn), and the metal oxide layer 174 disposed on the ruthenium oxide layer 172 may have a content of impurities, which is greater than that of the active layer 130. That is, when both the active layer 130 and the highly concentrated metal oxide layer 174 contain the metal oxide doped with the impurities, the highly concentrated metal oxide layer 174 may have a content of impurities greater than that of the active layer 130. Both the ruthenium oxide layer 172 and the highly concentrated metal oxide layer 174 may be formed by an area selective-atomic layer deposition method. On the other hand, the ruthenium oxide layer 172 and the highly concentrated metal oxide layer 174 may also be sequentially formed on the portion of the exposed surface of the active layer 130 by the deposition method using the mask.

As described above, in accordance with the exemplary embodiments, the contact layer for preventing the oxygen deficiency in the active layer may be provided between the active layer and the source and drain electrodes to prevent the active layer from being conductive and improve the switching characteristics.

In addition, the contact resistance between the active layer and the source and drain electrodes may be effectively reduced, and the characteristics and reliability of the element may be improved.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A thin film transistor comprising:
a gate electrode;
an active layer containing an oxide of a first metal element and disposed to be vertically spaced apart from the gate electrode;
a source electrode and a drain electrode disposed to be spaced apart from each other on the active layer; and
a contact layer containing a second metal element and disposed between the active layer and the source and drain electrodes.

2. The thin film transistor of claim 1, wherein the contact layer contains a metal or an alloy containing the second metal element.

3. The thin film transistor of claim 2, wherein the second metal element comprises ruthenium.

4. The thin film transistor of claim 1, wherein the contact layer contains an oxide of the second metal element.

5. The thin film transistor of claim 4, wherein the oxide of the first metal element and the oxide of the second metal element have compositions different from each other.

6. The thin film transistor of claim 4, wherein each of the oxide of the first metal element and the oxide of the second metal element contains zinc oxide doped with a plurality impurities, and
the oxide of the first metal element and the oxide of the second metal element have contents of the impurities, which are different from each other.

7. The thin film transistor of claim 6, wherein the oxide of the second metal element has a content of the impurities, which is greater than that of the oxide of the first metal element.

8. The thin film transistor of claim 6, wherein the impurities comprise at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (Tl), silicon (Si), germanium (Ge), tin (Sn), lead (Pb), phosphorus (P), or arsenic (As).

9. The thin film transistor of claim 6, wherein the oxide of the first metal element contains the impurities of approximately 20 at % or more and less than approximately 40 at % with respect to the entire oxide of the first metal element, and
the oxide of the second metal element contains impurities of approximately 40 at % or more and less than approximately 60 at % with respect to the entire oxide of the second metal element.

10. The thin film transistor of claim 6, wherein the oxide of the second metal element has a content of oxygen (O) less than that of the oxide of the first metal element.

11. The thin film transistor of claim 1, wherein the contact layer has a thickness of approximately 30 Å to approximately 100 Å.

12. The thin film transistor of claim 1, further comprising an insulating layer disposed on the active layer and having a contact hole through which a portion of a surface of the active layer is exposed,
wherein the contact layer is disposed on the portion of the surface of the active layer, which is exposed by the contact hole, and
the source and drain electrodes are in contact with the contact layer to extend onto the insulating layer.

13. A method for manufacturing a thin film transistor, the method comprising:
preparing a substrate on which a gate electrode and an active layer disposed to be vertically spaced apart from the gate electrode are formed; and
forming a contact layer for connecting the active layer to source and drain electrodes on the active layer.

14. The method for manufacturing a thin film transistor of claim 13, wherein the preparing of the substrate comprises preparing the substrate on which an insulating layer having a contact hole, through which a portion of a surface of the active layer is exposed, on the active layer, and
the forming of the contact layer comprises forming the contact layer on the portion of the surface of the active layer, which is exposed by the contact hole.

15. The method for manufacturing a thin film transistor of claim 14, wherein, in the forming of the contact layer, the contact layer is formed to a thickness of approximately 30 Å to approximately 100 Å on the portion of the surface of the active layer.

16. The method for manufacturing a thin film transistor of claim 13, wherein the forming of the contact layer is performed by an atomic layer deposition process in which a process cycle comprising supplying a source gas containing a metal element onto the active layer and supplying a reactant gas containing oxygen onto the active layer is repeated several times.

17. The method for manufacturing a thin film transistor of claim 16, wherein, in the supplying of the source gas, a first source gas containing zinc (Zn) and a second source gas containing at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), boron (B), thallium (TI), silicon (Si), germanium (Ge), tin (Sn), lead (Pb), phosphorus (P), or arsenic (As) are supplied at the same time.

18. The method for manufacturing a thin film transistor of claim 17, wherein, in the supplying of the source gas, the source gas is controlled to be supplied so that a supply amount of the second source gas is greater than a supply amount of the first source gas.

19. The method for manufacturing a thin film transistor of claim 13, further comprising forming a source electrode and a drain electrode on the contact layer.

20-34. (canceled)
